(19) United States
(12) Patent Application Publication
(10) Pub. No.: US 2024/0421077 A1
(43) Pub. Date: Dec. 19, 2024

(54) DIE STITCHING FOR STACKING ARCHITECTURE IN SEMICONDUCTOR PACKAGES

(71) Applicant: Taiwan Semiconductor Manufacturing Co., Ltd., Hsinchu (TW)

(72) Inventors: Hung-Pin Chang, New Taipei City (TW); Wei-Cheng Wu, Hsinchu (TW); Der-Chyang Yeh, Hsinchu (TW)

(21) Appl. No.: 18/506,641

(22) Filed: Nov. 10, 2023

Related U.S. Application Data
(60) Provisional application No. 63/508,334, filed on Jun. 15, 2023.

(51) Int. Cl. H01L 23/528; H01L 21/768; H01L 23/00; H01L 23/58; H01L 25/065

(52) U.S. Cl. CPC H01L 23/528; H01L 21/768; H01L 23/585; H01L 24/08; H01L 24/80; H01L 25/0652; H01L 2224/08145; H01L 2224/80895; H01L 2224/80896

(57) ABSTRACT

A package device for 3D stacking of integrated circuits includes a semiconductor substrate, and an interconnect structure on the semiconductor substrate. The interconnect structure is organized into a plurality of device regions, and the device has a first seal ring extending vertically through the interconnect structure in a first device region, and a second seal ring extending vertically through the interconnect structure in a second device region. The interconnect structure also includes a conductive line electrically connecting a metallization pattern within the first seal ring to a second metallization pattern within the second seal ring, wherein the first horizontally extending conductive line extends through the first seal ring and the second seal ring.

### PRIORITY CLAIM AND CROSS-REFERENCE

This application claims the benefits of U.S. Provisional Application No. 63/508,334, filed on Jun. 15, 2023, which application is hereby incorporated herein by reference in its entirety.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate three-dimensional aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified view of first embodiments of a package device in cross-sectional view.

FIGS. 2A-2C, 3, 4A-4C, and 5 illustrate various embodiment package devices in top-down view.

FIGS. 6-13 illustrate stages in an exemplary manufacturing process for forming a package device.

FIG. 14 is a flow chart illustrating an exemplary method of manufacturing a package device employing advantageous features disclosed herein.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, integrated circuit packages are formed by directly bonding integrated circuit dies to a bottom wafer that contains additional integrated circuits therein. This wafer and/or the integrated circuits formed therein may sometimes be referred to herein as an active interposer. A molding compound is dispensed around the integrated circuit dies as an encapsulant. In some embodiments a high level of integration and a high level of manufacturing flexibility is obtained by designing the bottom wafer such that it contains multiple integrated circuits, separated by respective scribe lines (by which the multiple integrated circuits can be separated at an appropriate stage of the manufacturing processes described herein). Even more preferably, each of these multiple integrated circuits includes an interconnect structure (typically a vertical stack of patterned conductive layers disposed within respective dielectric layers and vertically interconnected through respective layers of conductive vias) that is organized into a plurality of different device regions. Each of these device regions can accommodate a top integrated circuit being bonded thereon or thereto and each of these device regions preferably has an associated seal ring formed in the interconnect structure that electrically isolates signals within that device region from interference by or with other signals, such as signals within an adjacent device region or signal originating from without the device. Yet even greater manufacturing efficiency and flexibility can be obtained if the device allows for electrical connections to be made between the circuitry of one device region and the circuitry of an adjacent device region, notwithstanding the presence of the seal rings that otherwise serve to isolate the respective device regions. As used herein, the term isolate is meant in a broad sense, meaning to reduce, attenuate, or minimize noise and/or signal interference that might otherwise exist, but for the presence of the seal ring. The term isolate is not meant to denote or imply full and complete elimination of noise and or interference.

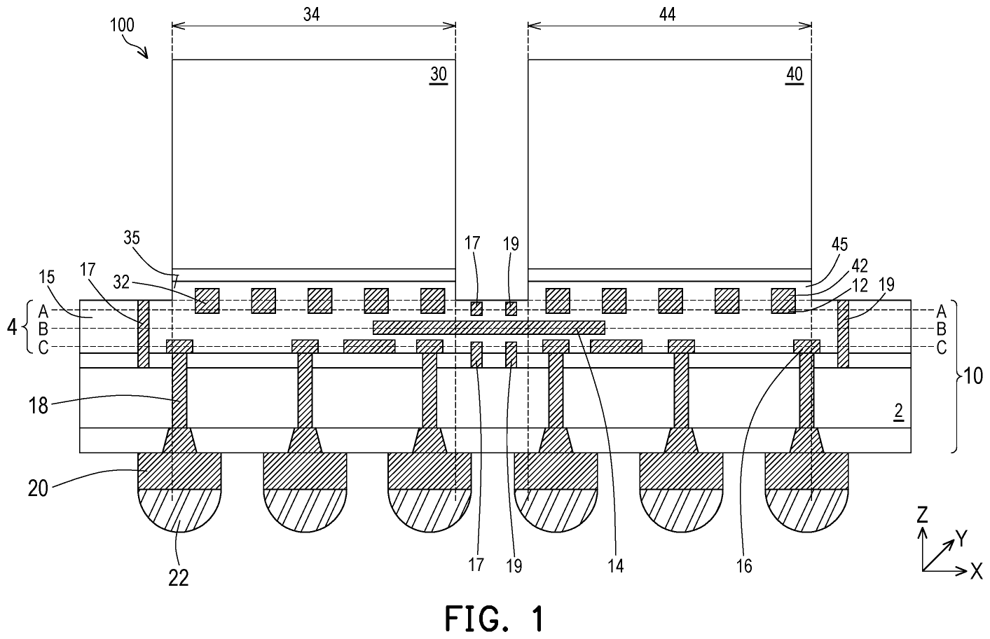

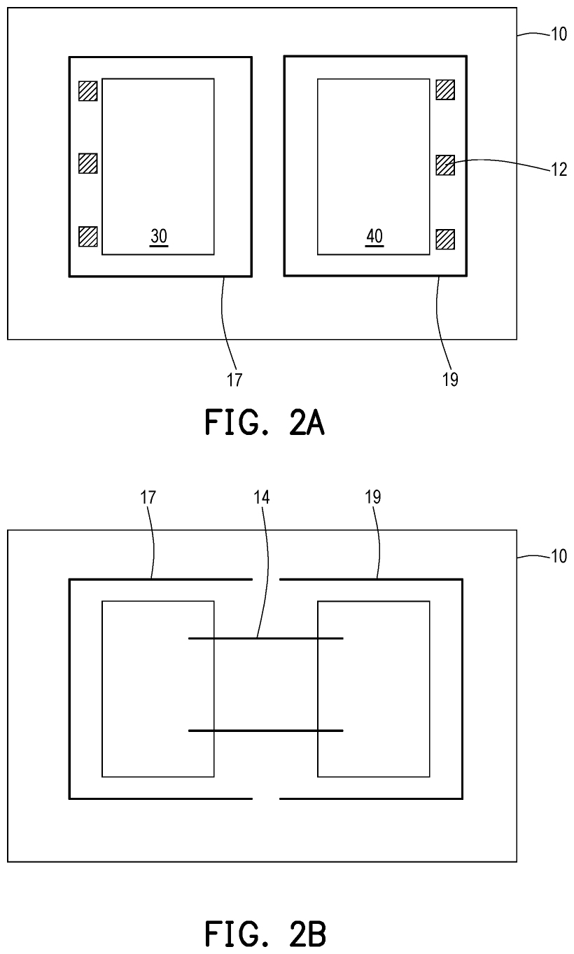

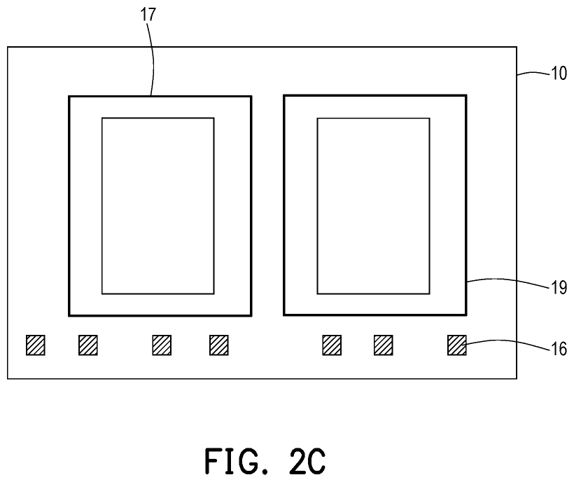

FIGS. 1 and 2A-2C provide a simple illustration that reveals advantageous features of embodiments described herein. In FIG. 1, a package device 100 is shown in cross-sectional view. Package device 100 includes a bottom structure 10, which in some embodiments is an integrated circuit device having substrate 2, and interconnect structure 4 on substrate 2. Bottom structure may include active devices, such as transistors on and/or at least partially within substrate 2, as those skilled in the art will understand. Bottom structure 10 may also be referred to herein as a bottom integrated circuit (IC), and may also be referred to herein as an active interposer. Interconnect structure 4 includes a stack of metallization layers formed within a stack of respective dielectric layers. In the illustrated embodiment, interconnect structure 4 includes a top metallization layer in which are formed contact pads 12, an intermediate metallization layer in which are formed one or more conductors 14, and a bottom metallization layer in which are formed one or more interconnect conductors 16. As used herein and elsewhere in this disclosure unless otherwise indicated expressly or by the context, an intermediate layer refers to a layer in a vertical stack of layers that is between a top layer of the stack and a bottom layer of the stack. Also shown in FIG. 1 are through substrate vias (TSVs) 18 which extend through substrate 2 and electrically connect, e.g., interconnect conductors 16 to external components such as by electrical connection through bottom contacts 20 and external connectors 22.

FIG. 1 also illustrates a first top die 30 and a second top die 40 direct bonded to bottom structure 10. First top die 30 includes contact pads 32 and a top dielectric layer 35. Contact pads 32 are direct bonded to contact pads 12 of interconnect structure forming a metal-to-metal bond therebetween and hence forming a metallization bond interface therebetween. Likewise, top dielectric layer 35 of top die 30 is direct bonded to a top dielectric layer 15 of interconnect structure 4 and hence a fusion bond interface is formed between top dielectric layer 35 and top dielectric layer 15. Similarly, contact pads 42 of second top die 40 are direct bonded to other contact pads 12 of interconnect structure 4, forming a metal-to-metal bond therebetween and hence forming a metallization bond interface therebetween. Likewise, top dielectric layer 45 of top die 40 is direct bonded to top dielectric layer 15 of interconnect structure 4 and hence a fusion bond interface is formed between top dielectric layer 45 and top dielectric layer 15.

Also shown in FIG. 1 is first die region 34 and second die region 44, sometimes referred to herein as first device region 34 and second device region 44, respectively. First die region 34 is defined by a projection of the periphery of first top die 30 onto underlying interconnect structure 4, and second die region 44 is defined by a projection of the periphery of second top die 40 onto underlying interconnect structure 4. In other words, first die region 30/second die region 40 is not a physical property of the structure, but rather is a logical construct for organizing interconnect structure 4 into regions that correspond to the respective top die, such as first top die 30 and second top die 40. One skilled in the art will recognize that although two top die are illustrated in the cross-sectional view of FIG. 1, additional top die may be bonded to bottom structure 10 in other cross-sectional planes. Similarly, in other embodiments, three, four, or more top die could be bonded to bottom structure in the plane illustrated in FIG. 1.

Each die region has associated with it a seal ring extending vertically through interconnect structure 4. For instance, first seal ring 17, associated with first die region 34 is shown in cross-sectional view in FIG. 1, and second seal ring 19, associated with second die region 44, is likewise shown in cross-sectional view in FIG. 1. Note that the respective seal rings extend from the top layer of interconnect structure 4 to the bottom layer of interconnect structure 4. In this way, first seal ring 17 can isolate signals carried by circuitry within first die region 34 from interference from signals arising outside of first die region 34 (e.g., cross-talk from signals being carried by circuitry within second die region 44). Likewise, second seal ring 19, by surrounding second die region 44, can isolate signals carried by circuitry within second die region 44 from interference from signals arising outside of second die region 44 (e.g., cross-talk from signals being carried by circuitry within first die region 34). One skilled in the art will recognize that first seal ring 17 and second seal ring 19 are preferably tied to a ground node, or other defined voltage level, in order to effectively shield the respective device regions from external signal interference.

A further understanding of advantageous features of the embodiment illustrated in FIG. 1 is provided by reviewing FIG. 1 in conjunction with FIGS. 2A, 2B, and 2C, which illustrate a top-down view of package device 100 along a first x-y plane A-A (as indicated by line A-A of FIG. 1), along a second x-y plane B-B (as indicated by line B-B of FIG. 1), and along a third x-y plane C-C (as indicated by line C-C of FIG. 1), respectively. For context, the cross-sectional view of FIG. 1 is taken along an x-z plane.

The first x-y plane A-A shown in FIG. 2A is at the top level of interconnect structure 4 wherein contact pads 12 are formed. Note that at this top level, first seal ring 17 surrounds first die region 34 (recall that first die region 34 is a logical construct defined by projecting a periphery of first top die 30 onto underlying interconnect structure 4). In this embodiment, first seal ring comprises a first conductor, formed in the top metallization layer of interconnect structure 4, which first conductor forms a closed polygon, in this case the closed polygon being a rectangle. As die, such as top die 30, are generally rectangular in shape, first seal ring 17 is generally rectangular in shape as well (being a projection of the outer boundary of top die 30). In other embodiments, first seal ring 17 may have a different shape, one that corresponds to but does not exactly match the periphery of top die 30. For instance, in some embodiments manufacturing constraints, spacing constraints, or even performance constraints might dictate a seal ring that forms a polygon of similar but not exactly the same shape and dimensions as those of the top die to which the seal rings corresponds. In yet other embodiments, the corners of a seal ring might be rounded either by design or as an artifact of manufacturing process variations. It should also be noted that a seal ring need not be of the same size and dimensions as the top die to which the seal ring corresponds. In the illustrated embodiments, a top die (30, 40, etc.) with length and width dimensions of X and Y (in an x-y plane) will have a corresponding seal ring formed of a polygon(s) also having length and width dimensions of X and Y. This is not always the case, however. It is within the contemplated scope of the present disclosure that is some embodiments a seal ring could encompass a die region that is greater than the area of the corresponding top die (i.e., having dimensions larger than X and Y), where in other embodiments, a seal ring could encompass a die region that is less than the area of the corresponding top die (i.e., having dimensions less than X and Y). One skilled in the art, once informed by the present disclosure, will be able to determine numerous variations and modifications to the size, shape, and dimensions of the seal ring, provided that sufficient signal isolation is provided and provided that manufacturing tolerances and design constraints are abided by. By surrounding first die region 34 with a grounded conductor that surrounds the region, the portion of first seal ring 17 illustrated in FIG. 2A serves to isolate circuitry within die region 34 (at least circuitry at the top metallization layer of interconnect structure 4) from signal interference, as explained above. Note that, because first seal ring 17 forms a grounded closed polygon that surrounds first die region 34, no conductors can extend through or across first seal ring 17 to carry signals into or out of first die region 34 (any such conductor would necessarily contact grounded first seal ring 17 and hence would likewise be grounded). This is both an advantageous feature (from the perspective of signal isolation) and a disadvantage feature (from the perspective of signal wire routing). Stated another way, if one desired to route a signal-carrying conductor from, e.g., within second die region 44 to within first die region 34, one would need to route the signal-carrying conductor either above or below first seal ring 17 (and as explained in the following paragraphs also above or below second seal ring 19). This results in added complexity and cost to manufacture package device 100.

As FIG. 2A further illustrates, second seal ring 19 surrounds second die region 44 (recall that second die region 44 is a logical construct defined by projecting a periphery of second top die 40 onto underlying interconnect structure 4). In this embodiment, second seal ring 19 comprises another first conductor, formed in the top metallization layer of interconnect structure 4, which first conductor forms another closed polygon, in this case the closed polygon being a rectangle. By surrounding second die region 44 with a grounded conductor that surrounds the region, second seal ring 19 serves to isolate circuitry within second die region 44 (at least circuitry at the top metallization layer of interconnect structure 4) from signal interference, as explained above. Note that, because second seal ring 19 forms a grounded closed polygon that surrounds second die region 44, no conductors can extend through or across second seal ring 19 to carry signals into or out of second die region 44 (any such conductor would necessarily contact grounded second seal ring 19 and hence would likewise be grounded). This is both an advantageous feature (from the perspective of signal isolation) and a disadvantage feature (from the perspective of signal wire routing). Stated another way, if one desired to route a signal-carrying conductor from, e.g., within first die region 34 to within second die region 44, one would need to route the signal carrying conductor either above or below second seal ring 19 (and as explained above also above or below first seal ring 17). This results in added complexity and cost to manufacture package device 100.

FIG. 2B will be discussed below, but first referring to FIG. 2C, first seal ring 17 and second seal ring 19 are illustrated at the x-y plane C-C, which corresponds to the bottom metallization layer of interconnect structure 4, wherein, e.g., interconnect conductors 16 are formed. At this level, similarly to the level illustrated in FIG. 2A, first seal ring 17 forms a closed, grounded polygon that surrounds first die region 34 (and hence any circuitry formed therein). Likewise, second seal ring 19 forms a closed, grounded polygon that surrounds second die region 44 (and hence any circuitry formed therein). As is clear from FIG. 2C, any electrical connection between circuitry of first die region 34 and second die region 44 would necessarily need to be routed above or below seal rings 17 and 19, lest the connection contact seal rings 17 and/or 19 and hence get grounded by them. As addressed above, this adds complexity and cost to the manufacture of package device 100 and limits the flexibility in revising or modifying the arrangement of respective top dies 30 and 40 and electrical connections thereto.

Turning now to FIG. 2B, which illustrates an intermediate metallization layer of interconnect structure 4. In this layer, first seal ring 17 comprises an open polygon having three sides corresponding to three respective sides of first die region 34 and being open along the region corresponding to a fourth side of first die region 34, in this instance the side of first die region 34 that is closest to, or adjacent, second die region 44. Similarly, second seal ring 19, at this level, comprises another open polygon having three sides corresponding to three respective sides of second die region 44 and being open along the region corresponding to a fourth side of die region 44, in this instance, the side of second die region 44 that is closest to, or adjacent, first die region 34. Also shown in FIG. 2B are horizontally extending conductors 14, sometimes referred to herein as simply conductors or electrical connections, and sometimes referred to a signal carrying conductors or connection. Sometimes, conductors 14 are referred to herein as stitching conductors because, as shown in FIG. 2B and explained further herein, these conductors serve to stitch together the electrical circuity of two or more die regions, such as the circuitry in die region 34 being stitched together by conductors 14 with the circuitry contained within second die region 44. Conductors 14 are formed in the same metallization layer of interconnect structure 4 as are the open polygon conductors of seal rings 17 and 19, respectively, also illustrated in FIG. 2B. Note that, because seal rings 17 and 19, respectively, comprise open polygons in this metallization layer, conductors 14 can extend across the respective seal rings, and hence can extend from within first die region 34 to within second die region 44 without being grounded through contact with the respective seal rings. This allows for a designer to route electrical signal connections between the various device regions, and between the various top die 30, 40, etc. mounted to bottom structure 10 within the interconnect structure 4 (or more precisely within the intermediate metallization layer of interconnect structure 4) and hence avoid the need to route such signal connections above or below the interconnect structure.

While FIGS. 1 and 2A-2B illustrate a fairly simple arrangement having only two top die and only three metallization layers, one skilled in the art will recognize that the teaching provided herein can be extended to more complex arrangements, including top die mounted onto bottom structure 10 in a two-dimensional array, more than two conductors 14 extending between device regions, and more than three metallization layers in interconnect structure 4, for instance. One way to broaden the teaching from the embodiments described above is by recognizing the interconnect structure may have N metallization layers in some embodiments, wherein N is a value of from three up to whatever practical limits may exist to manufacturing processes (recognizing that this level of abstraction applies not only to current limits of manufacturing processes, but also to higher limits as manufacturing technologies improve). In such embodiments, package device 100 preferably includes a seal ring that comprises N-X closed polygon conductors in N-X respective metallization layers of interconnect structure 4, and X open conductors in X respective intermediate metallization layers of interconnect structure, wherein X is a value of one or greater. As a practical matter, sufficient room is likely provided by one or perhaps two intermediate metallization layers to allow for interconnections between respective die regions. As a further practical matter, a closed polygon will provide better signal protection/isolation relative to an open polygon-and hence one skilled in the art will recognize that in most embodiments, the value for X should be minimized to the extent possible and practical (although this is a guide and not a hard and fast rule).

It should be noted that in the embodiments illustrated herein, first seal ring 17 and second seal ring 19 are illustrated as being of the same general shape and general dimensions. This is not a limitation on or a requirement of the present disclosure. In fact, as explained above, seal rings of different shapes, sizes, and dimensions-relative to their respective top die-are within the scope contemplated herein. Likewise, it is contemplated that, as an example, first seal ring 17 can be of a first shape (such as a rectangle) and second seal ring 19 can be of a second shape (such as a polygon with some number of sides other than four sides, an irregular polygon, curved shape such as a circle an ellipse, a polygon with rounded corners, or the like). As another example, first seal ring 17 can have first dimensions X and Y (corresponding to but not necessarily equal to the length and width of first top die 30), and second seal ring 19 can have second dimensions X′ and Y′ which are different than X and Y (corresponding to but again not necessarily equal to the length and width of second top die 40). In yet other embodiments, a package device 100 is contemplated having seal rings 17, 19, etc. that are of a standard size and shape sufficient to provide adequate signal isolation to a variety of different top die that might be bonded to bottom structure 10, thus providing a highly flexible standard package device that can accommodate a variety of different integrated circuits, depending upon the application. The ability to route signal-carrying conductors from one die region to another die region will be an advantageous feature to further increase the flexibility of such a package device. A yet further extension of the illustrated embodiments is that the closed polygon of first seal ring 17 formed in the top layer of interconnect structure 4 (illustrated in FIG. 2A) and the closed polygon of first seal ring 17 formed in the bottom layer of interconnect structure 4 (illustrated in FIG. 2C) can have different shapes, sizes, and/or dimensions relative to one another. For instance, greater signal isolation may be desirable at a top layer of interconnect structure 4 relative to a bottom layer of interconnect structure 4 due to higher risks of signal interference at the upper layer. On the other hand, packing density may be of greater concern at the bottom layer of interconnect structure relative to the top layer. In such an instance, on skilled in the art will recognize that the size, shape, and/or dimensions of first seal ring 17 at the top layer of interconnect structure 4 could be optimized for signal isolation, thus resulting in a first configuration for the closed polygon at that layer, whereas the size, shape, and/or dimensions of first seal ring 17 at the bottom layer of interconnect structure 4 could be optimized for packing density, thus resulting in a second configuration, different from the first configuration for the closed polygon at that layer. Similar considerations apply to the open polygon at the intermediate layer of interconnect structure 4 (illustrated at FIG. 2B), and similar considerations apply to other seal rings that might be employed, such as second seal ring 19.

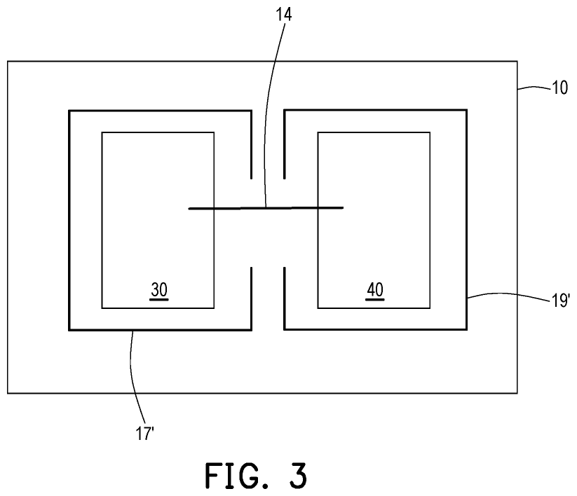

Note that in the embodiment shown in FIG. 2B, first seal ring 17 is completely open in the region corresponding to the side of first die region 34 closest to second die region 44 and second seal ring 19 is completely open in the region corresponding to the side of second die region 44 closest to first die region 34. By contrast, FIG. 3 illustrates an alternative embodiment in which first seal ring 17′ extends, at least partially, along regions corresponding to all four sides of first die region 34, and seal ring 19′ extends, at least partially, along regions corresponding to all four sides of second die region 44. In this embodiment, first seal ring 17′ extends partly along the region corresponding to the side of first device region 34, but does not extend fully along this region, thus providing a gap in (this level of) first seal ring 17′ through which one (or more) signal carrying conductor(s) 14 can pass, as shown. In this embodiment, first seal ring 17′ preferably has the same form at the top metallization layer as does first seal ring 17 as illustrated in FIG. 2A, and preferably has the same form at the bottom metallization layer as does first seal ring 17 as illustrated in FIG. 2C. Likewise, seal ring 19′ preferably has the same form at the top metallization layer as does seal ring 19 as illustrated in FIG. 2A, and preferably has the same form at the bottom metallization layer as does seal ring 19 as illustrated in FIG. 2C.

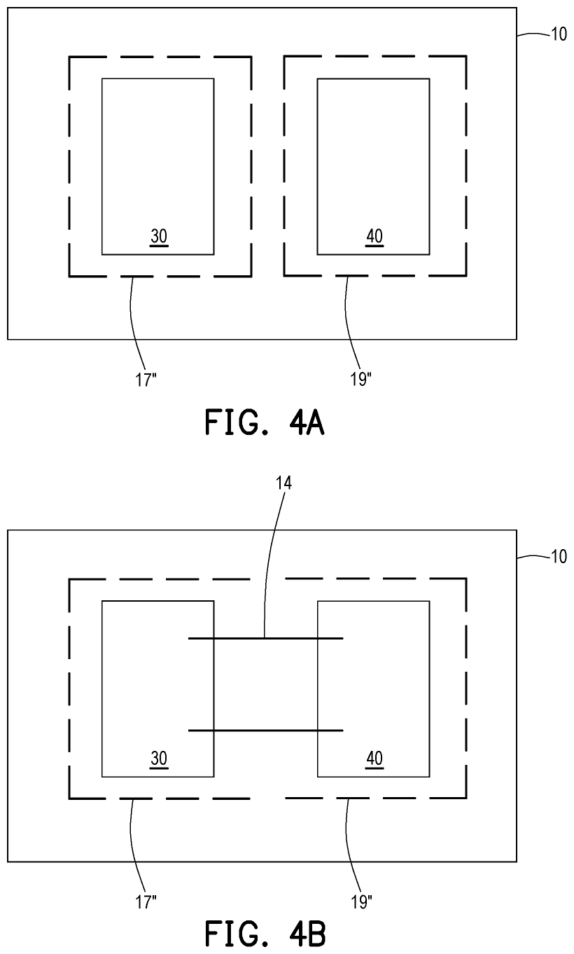

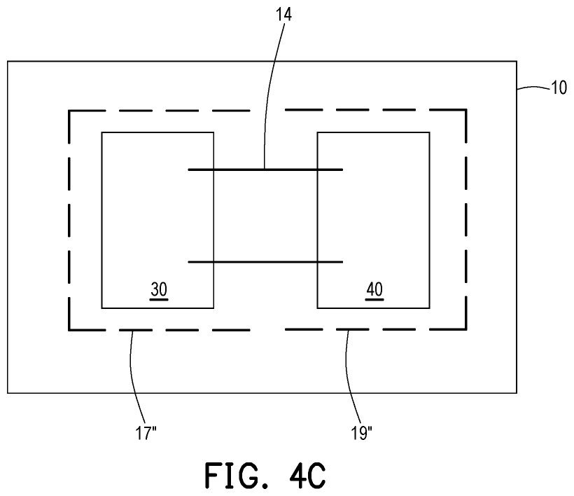

FIGS. 4A through 4C illustrate yet another embodiment, in which seal ring 17″ and seal ring 19″ are formed of discontinuous conductive segments. In other words, rather than having polygons formed of conductors forming continuous, unbroken line segments such as illustrated in FIGS. 2A, 2B, and 2C, seal rings 17″ and 19″ illustrated in FIGS. 4A, 4B, and 4C, have polygons formed of a series of discontinuous line segments that collectively form the respective polygons. As a matter of design choice, the discontinuous line segments illustrated in FIGS. 4A, 4B, and 4C may provide sufficient signal isolation (depending upon factors such as the power and frequency of signals carried within the respective die regions, the power and frequency of signals and noise interference sought to be reduced or eliminated, the size and spacing of the respective discontinuous segments, and the like). One skilled in the art can determine an optimum arrangement for the form of the polygons through routine experimentation, once informed by the present disclosure. In yet another embodiment, not illustrated herein, seal rings 17′ and 19′, illustrated in FIG. 3, could likewise be formed of discontinuous line segment conductors, such as illustrated in FIG. 4B (albeit maintaining the form factor shown in FIG. 3).

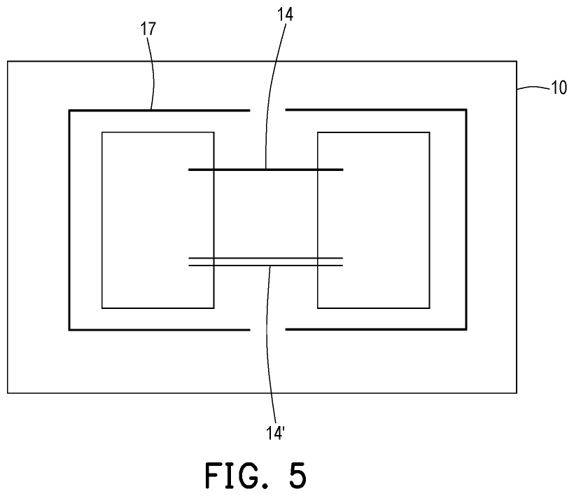

In each of the above described and illustrated embodiments, stitching conductor 14 is formed at only one level of the multi-layer interconnect structure 4. This need not always be the case. Of course, if only a single conductor 14 is formed, it will necessarily be formed in only a single level or metallic layer. In the embodiments illustrated by FIG. 2B and 4B, two conductors 14 are shown and both of these conductors are formed in the same layer of interconnect structure 4, i.e., in the x-y plane B-B, or stated another way in the same intermediate metallization layer of interconnect structure 4. FIG. 5 illustrates yet another embodiment, wherein a first conductor 14 is formed in a first intermediate metallization layer (such as the layer in the x-y plane B-B shown in FIGS. 2B, 4B, and 5), and wherein a second stitching conductor 14′ is formed in a different intermediate metallization layer of interconnect structure 4-as indicated by the double line format of conductor 14′ in FIG. 5. This is to indicate that conductor 14′ is not actually visible in the x-y plane B-B (i.e. the intermediate metallization layer) illustrated in FIG. 5. Rather, conductor 14′ is formed in an intermediate layer that is below (or in other embodiments above) the intermediate metallization layer illustrated in FIG. 5. One skilled in the art will recognize that, depending upon the application and the total number of metallization layers of interconnect structure 4, conductors 14, 14′, etc., could be formed in two, three or more respective intermediate metallization layers. It should be clear to those skilled in the art that seal rings 17/19 (or 17′/19′ in some embodiments) would need to form respective open polygons in the intermediate metallization layers in which stitching conductors 14, 14′ are formed. In other words, if two stitching conductors are formed in two separate metallization layers (say, layer M3 and M4), then the seal rings in both layers M3 and M4 must form open polygons (to allow for the stitching conductors to cross the seal rings without being shorted to ground). Other variations in the placement and arrangement of stitching conductors 14, 14′, as well as of seal rings 17, 17′, 19, 19′ will be apparent to those skilled in the art, once informed by the present disclosure and with the application of routine experimentation. All such variations are within the contemplated scope of this disclosure and are intended to be covered by one or more of the claims appended hereto.

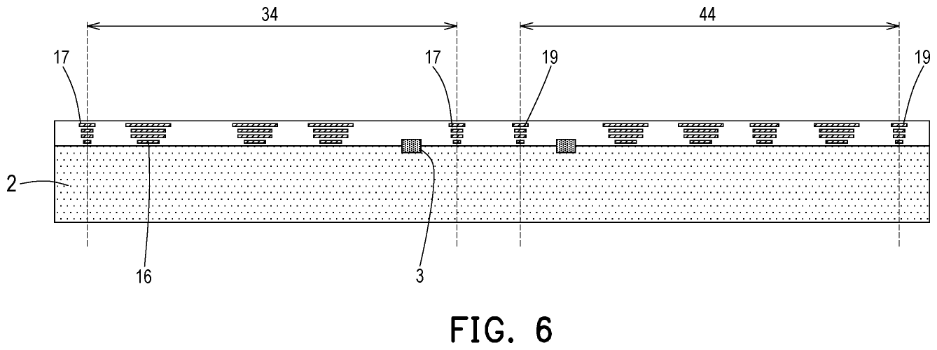

Turning now to FIGS. 6-13, which illustrate various stages in the manufacture of an exemplary package device 100′, FIG. 6 illustrates a stage of manufacture wherein one or more devices 3, such as transistors, diodes, and the like have been formed in and/or on substrate in a series of processes commonly known as front end of line (FEOL) processes. Also shown in FIG. 6 are several layers, in this example four layers, of interconnect structure have been formed using a series of processes commonly known as back end of line (BELO) processes. While it is contemplated that the layers of interconnect structure will be formed using damascene processes, any process for forming stacked conductors will suffice. As shown, portions of first seal ring 17 and portions of second seal ring 19, respectively, are formed in each of the lower layers of interconnect structure 4. As discussed above with respect for FIG. 2A, these portions of first seal ring 17 and second seal ring 19, respectively, will be in the form of closed polygons, each formed in the respective dielectric layers of interconnect structure 4. As discussed above, the four layers of first seal ring 17 shown in FIG. 6 are electrically connected together through conductive vias extending vertically from one layer to a next vertically adjacent layer as is well-known in the art. Four layers of interconnect conductors 16 are also shown in the four layers of interconnect structure illustrated in FIG. 6, illustrated schematically for clarity and ease of comprehension. Finally, first die region and second die region 44 are shown for context.

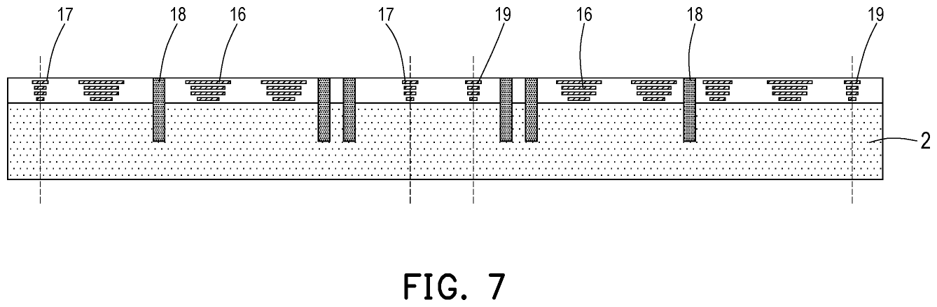

Through substrate vias (TSVs) 18 are next formed extending from interconnect structure 4 and at least partially through substrate 2, as illustrated in FIG. 7. In the illustrated embodiment, TSVs 18 are formed after four levels of interconnect structure 4 have been formed and TSVs 18 extend up to the level of the fourth layer of interconnect structure 4. In other embodiments, TSVs 18 are formed before interconnect structure 4 is formed, whereas in other embodiments, TSVs 18 are formed after only one or two layers of interconnect structure 4 are formed, and in yet other embodiments TSVs 18 are formed after five or more layers of interconnect structure 4 are formed. This is a matter of design choice. It should also be noted that, to provide even more manufacturing and design flexibility, respective TSVs 18 can be formed in different layers of interconnect structure 4, with some TSVs extending to a lower layer of interconnect structure 4 and other TSVs extending up to higher layers of interconnect structure 4.

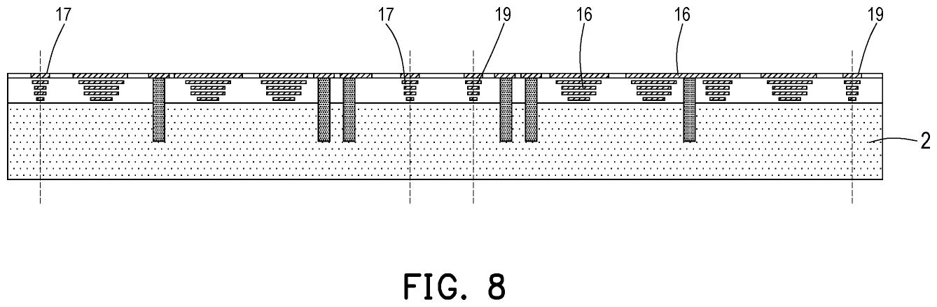

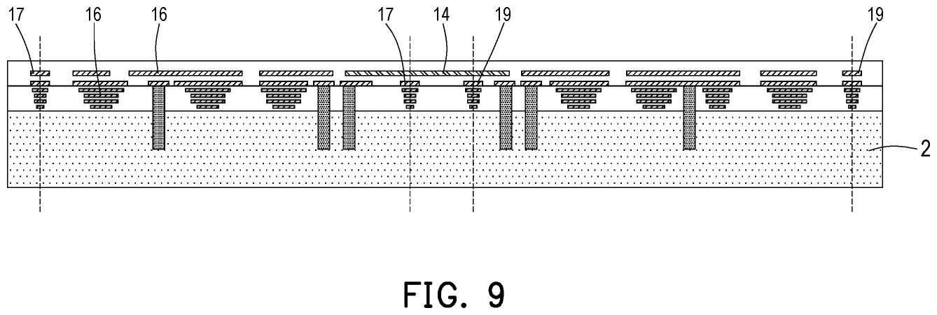

Continuing on to FIG. 8, a next layer of interconnect structure 4 is shown, in this embodiment, a fifth layer. This layer includes another layer for first seal ring 17 and second seal ring 19, respectively, as well as additional interconnect conductors 16, which may include, for instance, landing pads for the respective TSVs 18. In some embodiments, the state of interconnect structure 4 shown in FIG. 8 corresponds to what would otherwise be considered a completed interconnect structure-meaning one that provides for electrical interconnection of circuit elements within the respective die regions and provides for signal isolation of the respective die regions, and provides for contact pads (formed in the top layer of interconnect conductors 16 shown in FIG. 8). Hence, in some instances, the top layer of interconnect structure 4 shown in FIG. 8 might be referred to as a metal cap layer. Processing continues, however, as shown in FIG. 9 with the formation of yet another layer for interconnect structure 4. In this layer, conductor 14 also known as stitching conductor 14 is formed. Note that conductor 14 can extend across the boundary of first seal ring 17 in this layer because, as explained above with reference to FIGS. 2B and 3, at this level first seal ring 17 is an open polygon and does not extend (or at least as shown in FIG. 3 does not fully extend) along the side of the polygon facing, or closest to, second die region 44. Likewise, conductor 14 can extend across the boundary of second seal ring 19 in this layer because at this level second seal ring 19 is an open polygon and does not extend (or at least as shown in FIG. 3 does not fully extend) along the side of the polygon facing, or closest to, first die region 43.

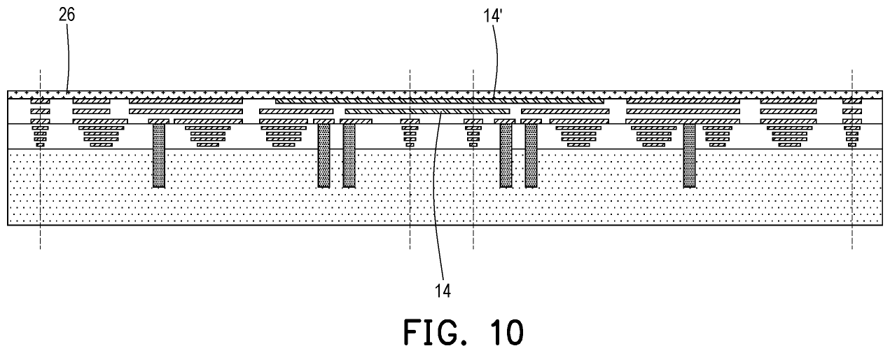

Continuing with FIG. 10, a next stage in the manufacture of package device 100′ is illustrated. In this illustration a next layer of interconnect structure 4 has been formed. This next layer includes conductor 14′ which, as illustrated, extends between first die region 33 and second die region 44, similarly to conductor 14. Again, in this layer, first seal ring 17 forms an open polygon and second seal ring 19 forms an open polygon, thus allowing conductor 14′ to cross the respective boundaries of first seal ring 17 and second seal ring 19. While in some embodiments conductor 14′ serves to electrically connect one (or more) interconnect conductors 16 located within first die region 34 to one (or more) interconnect conductors 16 located within second die region 44, in this illustrated embodiment conductor 14′ serves to directly interconnect first die 30 and second to die 40 as will be illustrated in the next figures. In such embodiments, conductor 14′ may be referred to as a die-to-die or a D2D connection. Also shown in FIG. 25 is an upper dielectric layer 25 formed over conductor 14′, and also over the interconnect conductors 16 formed in the same layer of interconnect structure 4 as is conductor 14′. In some embodiments, this upper dielectric layer is a passivation layer or a polymer layer, for instance.

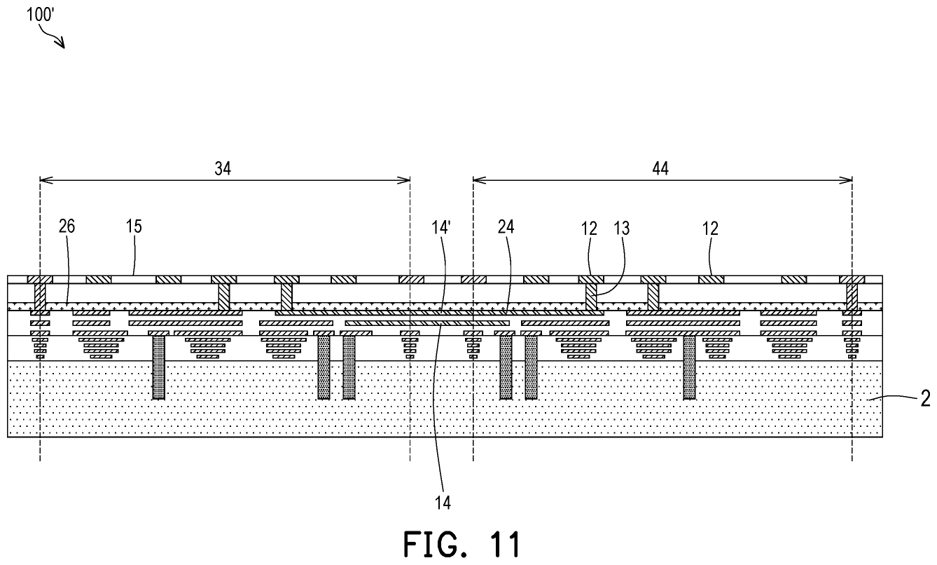

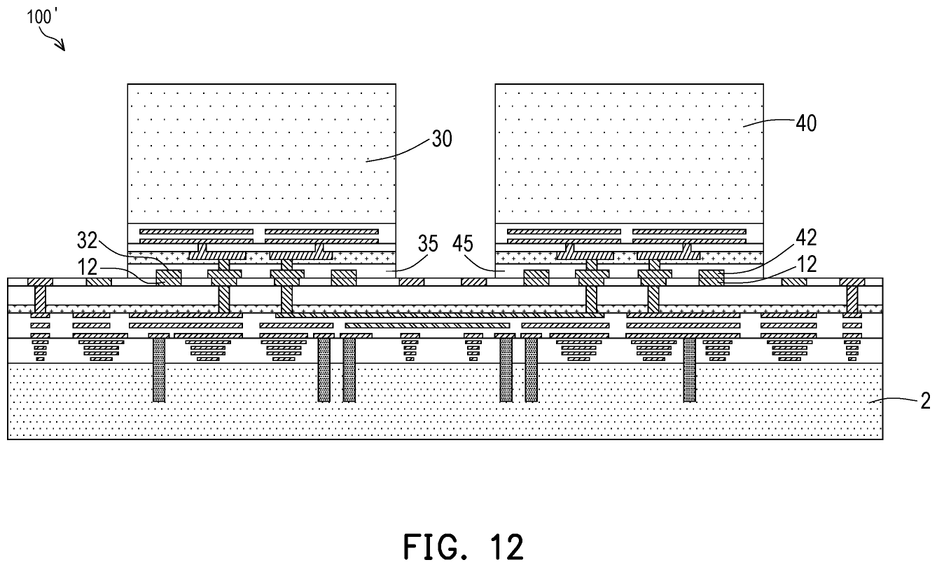

Processing continues as shown in FIG. 11 with the formation of a top layer of interconnect structure 4. The top layer includes contact pads 12 that are embedded within top dielectric layer 15. FIG. 11 also illustrates conductive vias 13 that electrically interconnect vertically adjacent layers of interconnect structure 4. While not shown, conductive vias 13 will also extend vertically between lower layers of interconnect structure 4 to, e.g., electrically interconnect the various layers that form first seal ring 17 and second seal ring 19, respectively, and also various of the interconnect conductors 16. Note that conductor 14′ electrically interconnects a first contact pad 12 that lies within the boundary of first die region 33 and a second contact pad 12 that lies within the boundary of second die region 44. This allows for a direct connection between a first top die 30 mounted onto first die region 34 and a second top die 40 mounted onto the second die region 44, as best illustrated in FIG. 12.

FIG. 12 illustrates exemplary package device 100′ after first top die 30 and second top die 40, respectively, have been direct bonded onto bottom die 10. Contact pads 32 of first top die 30 form metal-metal bond with contact pads 12 of bottom die 10, and contact pads 42 of second top die 40 form metal-metal bonds with other contact pads 12 of bottom die 10. Similarly, dielectric layer 35 of first top die 30 forms a fusion bond with top dielectric layer 15 of bottom die 10, and dielectric layer 45 of second top die 40 forms a fusion bond with top dielectric layer 15 of bottom die 10. Note that one contact pad 32 of first top die 30 is electrically interconnected with a contact pad 42 of second top die 40 by way of D2D conductor 14′.

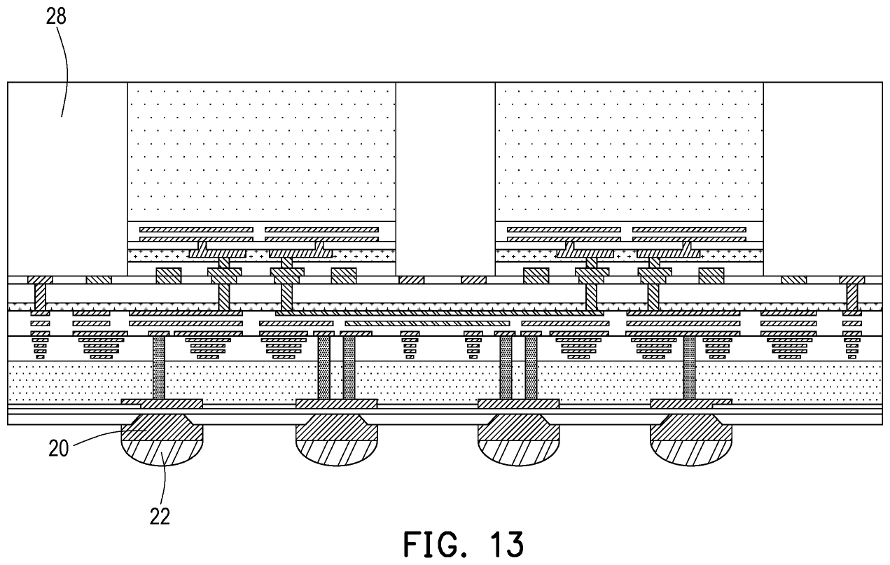

FIG. 13 represents the result of still more processing on package device 100′. Substrate 2 has been thinned back from the backside in order to expose TSV 19, contact pads 20, which may include under bump metal (UBM) have been formed on the respective exposed ends of TSVs 18, and external connectors 22, which may be solder balls, solder bumps, C4 connectors, or the like, have been connected to respective contact pads 20. As also shown in FIG. 13, one or more encapsulants 28, which may include underfill materials, molding compounds, heat dissipation elements, and the like, are formed to encapsulate surfaces of first top die 30, second top die 40, and bottom die 10, respectively.

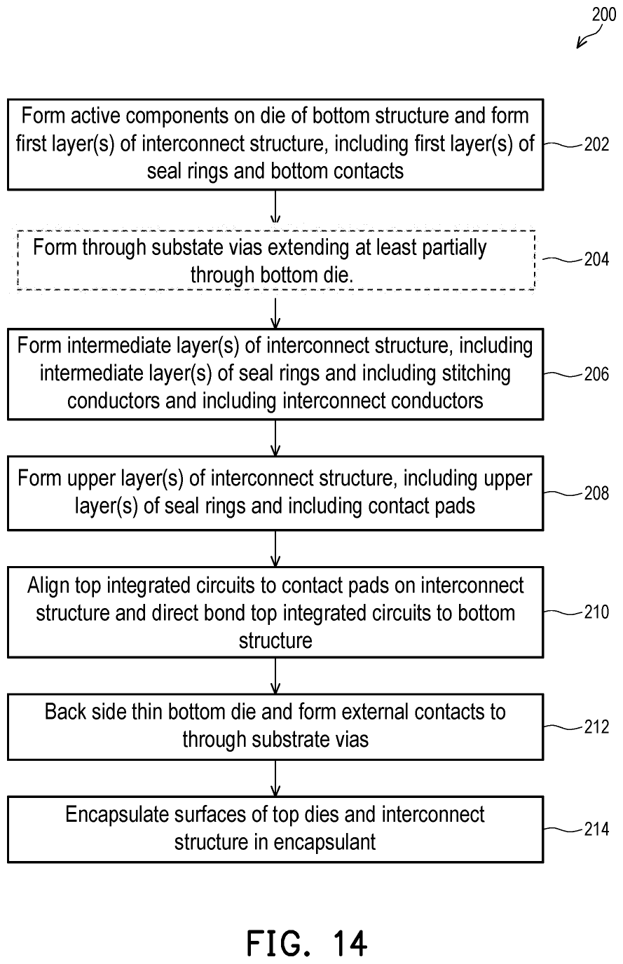

FIG. 14 is a flowchart illustrating an exemplary method 200 of manufacturing a package device having some of the advantageous features disclosed herein. In a first step 202 active components are formed on a bottom structure die and first layer(s) of an interconnect structure, including first layer(s) of seal rings and bottom contacts, are formed. In a next step 204 through substrate vias extending at least partially through the bottom die are formed. This is an optional step, as indicated by the dotted line of step 204. A next step 206 involves forming intermediate layer(s) of the interconnect structure, including intermediate layer(s) of seal rings and including stitching conductors and including interconnect conductors. Then, upper layer(s) of the interconnect structure, including upper layer(s) of seal rings and including contact pads, are formed as represented by step 208. In step 210, top integrated circuits are aligned to contact pads on the interconnect structure and the top integrated circuits are direct bonded (metal-to-metal bonds, and/or dielectric fusion bonds) to the bottom structure. In another optional step, 212, the bottom die is thinned from the backside and external contacts are formed on the exposed through substrate vias, if they were formed (in optional step 204). Finally, in step 214, underfill, molding compound, polymer, and/or the like may be formed to at least partially encapsulate surfaces of the top die and the interconnect structure.

One general aspect of embodiments disclosed herein includes a semiconductor substrate. The device also includes an interconnect structure on the semiconductor substrate, interconnect structure being organized into a plurality of device regions. The device also includes a first seal ring extending vertically through the interconnect structure in a first device region. The device also includes second seal ring extending vertically through the interconnect structure in a second device region. The device also includes and a first horizontally extending conductive line in the interconnect structure, the first horizontally extending conductive line electrically connecting a first metallization pattern within the first seal ring to a second metallization pattern within the second seal ring, where the first horizontally extending conductive line extends through the first seal ring and the second seal ring.

Another general aspect of embodiments disclosed herein includes a bottom integrated circuit (IC) including an interconnect structure. The package also includes a first top IC having contact pads forming metallic bond interfaces with respective contact pads of the bottom IC and having a first top dielectric layer forming a fusion bond interface with a top dielectric layer of the bottom IC, where a projection of an outer periphery of the first top IC defines a first die region in the interconnect structure. The package also includes a second top IC having contact pads forming metallic bond interfaces with respective contact pads of the bottom IC and having a second top dielectric layer forming a fusion bond interface with the top dielectric layer of the bottom IC, where a projection of an outer periphery of the second top IC defines a second die region in the interconnect structure. The package also includes a first seal ring including: a first conductor in a top layer of the interconnect structure, the first conductor forming a closed polygon that surrounds the first die region, a second conductor in a bottom layer of the interconnect structure, the second conductor forming a second closed polygon that surrounds the first die region, a third conductor in an intermediate layer of the interconnect structure, the third conductor forming a first open polygon, the first open polygon having three sides aligned to three respective sides of the first die region and being open along a side of the first die region that is closest to the second die region. The package also includes a second seal ring including: a fourth conductor in the top layer of the interconnect structure, the fourth conductor forming a closed polygon that surrounds the second die region, a fifth conductor in the bottom layer of the interconnect structure, the fifth conductor forming a second closed polygon that surrounds the second die region, a sixth conductor in the intermediate layer of the interconnect structure, the sixth conductor forming a second open polygon, the second open polygon having three sides aligned to three respective sides of the second die region and being open along a side of the second die region that is closest to the first die region. The package also includes a stitching conductor in the intermediate layer of the interconnect structure, the stitching conductor extending from the first die region to the second die region through the respective open sides of the first open polygon and the second open polygons.

A further general aspect of embodiments disclosed herein includes a method for forming a package, the method including fabricating a plurality of active components on a bottom integrated circuit (IC). The method also includes fabricating an interconnect structure over the bottom IC, by: depositing a stack of dielectric layers on the bottom IC, embedding within each dielectric layer a metallization layer, and electrically connecting vertically adjacent metallization layers through vertically extending conductive vias. The method further includes direct bonding onto the bottom IC a first top IC by metal-to-metal bonding contact pads of the first top IC onto contact pads of the bottom IC and by fusion bonding a first top dielectric layer of the first top IC onto a top dielectric layer of the stack of dielectric layers. The method also includes and direct bonding onto the bottom IC a second top IC by metal-to-metal bonding contact pads of the second top IC onto contact pads of the bottom IC and by fusion bonding a second top dielectric layer of the second top IC onto the top dielectric layer of the stack of dielectric layers. The method also includes where the step of fabricating an interconnect structure over the bottom IC also includes forming a top metallization pattern in a top metallization layer of the interconnect structure, the top metallization pattern forming a first closed polygon having a perimeter that is vertically aligned to a perimeter of the first top IC the top metallization pattern also forming a second closed polygon having a perimeter that is vertically aligned to a perimeter of the second top IC, and forming a bottom metallization pattern in a bottom metallization layer of the interconnect structure, the bottom metallization pattern forming a third closed polygon having a perimeter that is vertically aligned to a perimeter of the first top IC, the bottom metallization pattern also forming a fourth closed polygon having a perimeter that is vertically aligned to a perimeter of the second top IC, and forming an intermediate metallization pattern in an intermediate layer of the interconnect structure, the intermediate metallization pattern forming a first open polygon having a perimeter that is vertically aligned to a perimeter of the first top IC and having an open side vertically aligned with a side of the first top IC that is closest to the second top IC, the intermediate metallization pattern also forming a second open polygon having a perimeter that is vertically aligned to a perimeter of the second to IC and having an open side vertically aligned with a side of the second top IC that is closest to the first top IC, the intermediate metallization pattern also forming at least one conductive line extending from within the perimeter of the first open polygon to within the perimeter of the second open polygon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a semiconductor substrate;
an interconnect structure on the semiconductor substrate, interconnect structure being organized into a plurality of device regions;
a first seal ring extending vertically through the interconnect structure in a first device region;
second seal ring extending vertically through the interconnect structure in a second device region; and
a first horizontally extending conductive line in the interconnect structure, the first horizontally extending conductive line electrically connecting a first metallization pattern within the first seal ring to a second metallization pattern within the second seal ring, wherein the first horizontally extending conductive line extends through the first seal ring and the second seal ring.

2. The device of claim 1 wherein the first seal ring comprises
a first conductor in a first layer of the interconnect structure, wherein the first conductor forms a closed polygon that surrounds the first device region,
a second conductor in a second layer of the interconnect structure, below the first layer, wherein the second conductor forms an open polygon and partially surrounds the first device region; and
a third conductor in a third layer of the interconnect structure, below the second layer, wherein the third conductor forms a closed polygon that surrounds the first device region.

3. The device of claim 2, wherein the first horizontally extending conductive line is in the third layer of the interconnect structure.

4. The device of claim 2, wherein:
the interconnect structure comprises N conductive layers; and
the first seal ring comprises a stack of N-X conductors forming N-X respective closed polygons that respectively surround the first device region, and X conductors forming X respective open polygons that respectively partially surround the first device region; and
wherein N is a number greater than or equal to three and X is s number greater than or equal to one.

5. The device of claim 1, wherein the interconnect structure is divided into M device regions and further comprising M seal rings, each seal ring of the M seal rings providing signal isolation to circuitry within the corresponding device region and further comprising M−1 horizontally extending conductive lines, each horizontally extending conductive line electrically connecting circuitry in one of the M device regions to circuitry in an adjacent one of the M device regions.

6. The device of claim 1, wherein:
a top layer of the interconnect structure comprises dielectric layer having a top surface and a plurality of contact pads each contact pad of the plurality of contact pads having a top surface that is level with the top surface of the dielectric layer; and
further comprising a first integrated circuit on the first device region, the first integrated circuit having contacts pads forming respective metal bond interfaces with respective contact pads of the interconnect structure, and a second integrated circuit on the second device region, the second integrated circuit having contacts pads forming respective metal bond interfaces with respective contact pads of the interconnect structure.

7. The device of claim 6, further comprising a fusion bond interface between the dielectric layer of the interconnect structure and a top dielectric layer of the first integrated circuit, and a fusion bond interface between the dielectric layer of the interconnect structure and a top dielectric layer of the second integrated circuit.

8. The device of claim 1, wherein the semiconductor substrate and the interconnect structure on the semiconductor substrate are part of a bottom integrated circuit.

9. The device of claim 1, wherein the semiconductor substrate includes a plurality of bottom integrated circuit regions separated by scribe lines, each bottom integrated circuit region including an interconnect structure organized into a plurality of device regions, a plurality of seal rings, and a plurality of horizontally extending conductive line extending through adjacent seal ring.

10. A package comprising:
a bottom integrated circuit (IC) including an interconnect structure;
a first top IC having contact pads forming metallic bond interfaces with respective contact pads of the bottom IC and having a first top dielectric layer forming a fusion bond interface with a top dielectric layer of the bottom IC, wherein a projection of an outer periphery of the first top IC defines a first die region in the interconnect structure;
a second top IC having contact pads forming metallic bond interfaces with respective contact pads of the bottom IC and having a second top dielectric layer forming a fusion bond interface with the top dielectric layer of the bottom IC, wherein a projection of an outer periphery of the second top IC defines a second die region in the interconnect structure;
a first seal ring including:
a first conductor in a top layer of the interconnect structure, the first conductor forming a closed polygon that surrounds the first die region,
a second conductor in a bottom layer of the interconnect structure, the second conductor forming a second closed polygon that surrounds the first die region,
a third conductor in an intermediate layer of the interconnect structure, the third conductor forming a first open polygon, the first open polygon having three sides aligned to three respective sides of the first die region and being open along a side of the first die region that is closest to the second die region;
a second seal ring including:
a fourth conductor in the top layer of the interconnect structure, the fourth conductor forming a closed polygon that surrounds the second die region,
a fifth conductor in the bottom layer of the interconnect structure, the fifth conductor forming a second closed polygon that surrounds the second die region,
a sixth conductor in the intermediate layer of the interconnect structure, the sixth conductor forming a second open polygon, the second open polygon having three sides aligned to three respective sides of the second die region and being open along a side of the second die region that is closest to the first die region; and
a stitching conductor in the intermediate layer of the interconnect structure, the stitching conductor extending from the first die region to the second die region through the respective open sides of the first open polygon and the second open polygon.

11. The package of claim 10, wherein:
the first seal ring further comprises a seventh conductor in a second intermediate layer, the seventh conductor forming a third open polygon, the third open polygon having three sides aligned to three respective sides of the first die region and being open along a side of the first die region that is closest to the second die region;
the second seal ring further comprises an eighth conductor in the second intermediate layer, the eighth conductor forming a fourth open polygon, the fourth open polygon having three sides aligned to three respective sides of the second die region and being open along a side of the second die region that is closest to the first die region; and
the second intermediate layer further includes a second stitching conductor, the second stitching conductor extending from the first die region to the second die region through the respective open sides of the third open polygon and the fourth open polygon.

12. The package of claim 10, wherein the stitching conductor electrically connects at least one of the contact pads of the first top IC to at least one of the contact pads of the second top IC.

13. The package of claim 10, wherein the interconnect structure comprises N layers and wherein the first seal ring comprises N−1 closed polygons arranged in a vertical stack and one open polygon vertically aligned to the N−1 closed polygons and interjacent a topmost one of the N−1 closed polygons and a bottommost one of the N−1 closed polygons.

14. The package of claim 10, wherein the closed polygon that surrounds the first die region comprises continuous line segments.

15. The package of claim 10, wherein the closed polygon that surrounds the first die region comprises at least one line segment that is discontinuous.

16. The package of claim 10, wherein the first seal ring comprises a number of vertically arranged closed polygon structures, and the second seal ring comprises a second number of vertically arranged closed polygon structures.

17. The package of claim 10, further comprising:
N top ICs, each top IC having contact pads forming metallic bond interfaces with respective contact pads of the bottom IC and each top IC having a top dielectric layer forming a fusion bond interface with the top dielectric layer of the bottom IC, wherein a projection of an outer periphery of each top die IC defines one of N die regions in the interconnect structure, wherein the N top ICs includes the first top IC and the second top IC;
N seal rings, each seal ring including:
a conductor in the top layer of the interconnect structure and forming a closed polygon that surrounds the one of N die regions,
a conductor in the bottom layer of the interconnect structure, and forming a second closed polygon that surrounds the one of the N die regions,
a conductor in the intermediate layer of the interconnect structure, and forming an open polygon, the open polygon having three sides aligned to three respective sides of the one of the N die regions and being open along a side of the first die region that is closest to an adjacent one of the N die regions, wherein the N seal rings includes the first seal ring and the second seal ring; and
N−1 stitching conductors, each of the N−1 stitch conductors extending from within the one of the N die regions to within the adjacent one of the N die regions, wherein N−1 stitching conductors includes the stitching conductor.

18. A method for forming a package, the method comprising:
fabricating a plurality of active components on a bottom integrated circuit (IC);
fabricating an interconnect structure over the bottom IC, by:
depositing a stack of dielectric layers on the bottom IC,
embedding within each dielectric layer a metallization layer, and
electrically connecting vertically adjacent metallization layers through vertically extending conductive vias;
direct bonding onto the bottom IC a first top IC by metal-to-metal bonding contact pads of the first top IC onto contact pads of the bottom IC and by fusion bonding a first top dielectric layer of the first top IC onto a top dielectric layer of the stack of dielectric layers; and
direct bonding onto the bottom IC a second top IC by metal-to-metal bonding contact pads of the second top IC onto contact pads of the bottom IC and by fusion bonding a second top dielectric layer of the second top IC onto the top dielectric layer of the stack of dielectric layers;
wherein the step of fabricating an interconnect structure over the bottom IC also includes:
forming a top metallization pattern in a top metallization layer of the interconnect structure, the top metallization pattern forming a first closed polygon having a perimeter that is vertically aligned to a perimeter of the first top IC, the top metallization pattern also forming a second closed polygon having a perimeter that is vertically aligned to a perimeter of the second top IC,
forming a bottom metallization pattern in a bottom metallization layer of the interconnect structure, the bottom metallization pattern forming a third closed polygon having a perimeter that is vertically aligned to the perimeter of the first top IC, the bottom metallization pattern also forming a fourth closed polygon having a perimeter that is vertically aligned to the perimeter of the second top IC, and
forming an intermediate metallization pattern in an intermediate layer of the interconnect structure, the intermediate metallization pattern forming a first open polygon having a perimeter that is vertically aligned to the perimeter of the first top IC and having an open side vertically aligned with a side of the first top IC that is closest to the second top IC, the intermediate metallization pattern also forming a second open polygon having a perimeter that is vertically aligned to the perimeter of the second top IC and having an open side vertically aligned with a side of the second top IC that is closest to the first top IC, the intermediate metallization pattern also forming at least one conductive line extending from within the perimeter of the first open polygon to within the perimeter of the second open polygon.

19. The method of claim 18, further comprising arranging a series of line segments in the top metallization pattern and the bottom metallization pattern to form the first and second closed polygons.

20. The method of claim 18, wherein the interconnect structure comprises N metallization layers, and further comprising manufacturing N-X closed polygons and X open polygons to form a first seal ring beneath the first top IC, and manufacturing N-X other closed polygons and X other open polygons to form a second seal ring beneath the second top IC.
